(19) United States
(12) Patent Application Publication
(10) Pub. No.: US 2011/0221268 A1
(43) Pub. Date: Sep. 15, 2011

(54) Power Converter and In-Car Electrical System

(75) Inventors: Takuro Kanazawa, Hitachinaka (JP); Akira Mishima, Mito (JP); Kentaro Ochi, Hitachi (JP)

(73) Assignee: Hitachi, Ltd., Chiyoda-ku, Tokyo (JP)

(21) Appl. No.: 13/125,514

(22) PCT Filed: Oct. 22, 2009
(86) PCT No.: PCT/JP2009/068174

§ 371 Date: May 24, 2011

(30) Foreign Application Priority Data
Oct. 23, 2008 (JP) 2008-272716

(51) Int. Cl. H05K 7/00; B60L 1/00

(52) U.S. Cl. 307/10.1; 361/775

(57) ABSTRACT

Downsizing, cost reduction, and a low inductance of an input/output circuit are to be achieved with a power converter in which a multilayer board having a power semiconductor module 500 and busbars 11, 12 is modularized. The positive busbar 11 and the negative busbar 12 for feeding main circuit current are provided on a surface of the multilayer board 100 on which a control device 10a is mounted. The positive busbar 11 and the negative busbar 12 are formed to be thicker that the metal layer wiring in each layer of the multilayer board 100. The positive busbar 11 is electrically connected to the 2nth layer wiring (n represents a positive integer) from the positive surface wiring of the multilayer board 100, and the negative busbar 12 to the 2n+1th layer wiring opposite to the 2nth layer wiring of the multilayer board 100, through via holes. As a result, current flows into the power semiconductor module 500 in opposite directions through the 2nth layer wiring and the 2n+1th layer wiring. Thus the inductance of the main circuit is reduced, and downsizing and cost reduction of the high-output power converter energized by a large current can be achieved.

### TECHNICAL FIELD

The present invention relates to a power converter as represented by, for example, an inverter, on which a power semiconductor device, a control device and the like are mounted, which is widely used for home electric appliances, vehicles and industrial instruments, and to an in-car electrical system using the power converter.

### BACKGROUND ART

Conventionally, this kind of power converter is modularized by integrating a power semiconductor device with a control device and the like, and housed in, for example, a resin mold case or a metal case. Therefore, the power converter can be easily mounted on, for example, an in-car electrical system as a small compact power unit. In such a power converter, various kinds of improvements are adopted for a mounting method and an extraction method of a conductor wiring (busbar) for inputting/outputting a large current between the power converter and an external instrument. The following technology has been disclosed (for example, see Patent Document 1). For example, in a power unit where a large current wiring board is mounted on a power semiconductor module on which a power semiconductor device is mounted, a conductor wiring (busbar) formed on the large current wiring board for supplying a main current and a main circuit terminal of the power semiconductor module are directly connected by a screw in order to fix the large current wiring board and the power semiconductor module, while enabling assembly and maintenance of the power converter easy by forming a control terminal and a guide pin in the power semiconductor module so that the control terminal and the guide pin pass through the large current wiring board.

In addition, another technology of a mold resin type power converter has been disclosed (for example, see Patent Document 2), in which a power semiconductor device is mounted on a lead frame; a metal base and the lead frame are fixed sandwiching an insulating adhesive sheet therebetween; an exterior resin mold case is fixed to the metal base by an adhesive agent; a resin seal material is filled in the exterior resin mold case; and, the exterior resin mold case and circuit elements such as a semiconductor device mounted inside the exterior resin mold case are integrally sealed. According to the technology, a control board on which a microcontroller and a driver IC are mounted is located on the upper side of the metal base, and further, a wiring board on which an electrolytic capacitor and an input/output terminal table are mounted is arranged on the upper side of the control board. Therefore, a power converter modularized by using a thick lead frame can be downsized.

### PRIOR ART DOCUMENT

### Patent Document

[Patent Document 1] Japanese Patent Publication No. H05-94854
[Patent Document 2] Japanese Patent Publication No. 2000-245170

### SUMMARY OF THE INVENTION

### Problems to be Solved by the Invention

However, in the technology described in the Patent Document 1, since busbars formed on the large current wiring board are arranged in parallel in the lateral direction, a reduction of wiring inductance of the busbars is difficult due to the effects of lengths of the busbars and a mutual inductance between the busbars.

In addition, the technology described in the Patent Document 2 consists of many elements such as a metal base/lead frame/control board/wiring board/exterior resin mold case. Therefore, the cost reduction is difficult and a number of processes for mounting each of the elements increases. Furthermore, since the wiring board has a structure that stacks a thin wiring layer and an insulating layer alternately, the electric resistance and the thermal resistance are both increase, and as a result, it becomes difficult to apply a large current to the power converter.

Namely, with respect to a power converter consisting of a power semiconductor module on which a semiconductor device is mounted, a multilayer board on which a control unit where, for example, a driver IC is arranged is mounted, and a wiring portion on which an electrolytic capacitor and an inductor are mounted, a large cross section as well as a complex structure such as a laminate structure is required for the electric wiring of the wiring portion, in order to achieve a high-output by a large current application and a low inductance mounting. Therefore, in the conventional power converter, reduction in size and cost of the power converter as a whole by lowering an inductance of a main circuit current path is difficult.

The present invention was developed in consideration of the foregoing problems, and it is an object of the present invention to provide a power converter that can achieve reduction in size and cost and lowering of inductance of an input/output circuit with a structure that a power semiconductor module and a multilayer board on which a busbar is formed are integrally modularized, and to provide an in-car electrical system using the power converter.

### Means for Solving the Problems

In order to solve the foregoing problems, according to the present invention, there is provided a power converter which includes: a power semiconductor module on which a power semiconductor device is mounted; a control device for controlling the power semiconductor module; a multilayer board for mounting the control device; and a positive busbar and a negative busbar for inputting/outputting electric power to and from the power semiconductor module. The positive busbar and the negative busbar are mounted on one side of the multilayer board; the positive busbar is connected to a positive main circuit terminal of the power semiconductor module and a positive surface wiring on a surface mounted on the multilayer board, and the positive surface wiring is connected to a 2nth (n represents a positive integer) layer of wiring layers of the multilayer board through a first via hole or a first through-hole; the negative busbar is connected to a negative main circuit terminal of the power semiconductor module and a negative surface wiring on a surface mounted on the multilayer board, and the negative surface wiring is connected to a 2n+1th layer facing the 2nth layer of the multilayer board through a second via hole or a second through-hole; the positive main circuit terminal of the power semiconductor module and the positive busbar are electrically connected by a first fixing member (for example, screw); and the negative main circuit terminal of the power semiconductor module and the negative busbar are electrically connected by a second fixing member (for example, screw).

In addition, according to the present invention, there is provided a power converter which includes: a power semiconductor module on which a power semiconductor device is mounted; a control device for controlling the power semiconductor module; a multilayer board for mounting the control device; and a positive busbar and a negative busbar for inputting/outputting electric power to and from the power semiconductor module. The positive busbar is mounted on one side of the multilayer board and the negative busbar is mounted on the other side of the multilayer board, and the positive busbar and the negative busbar face each other; the positive busbar is connected to a positive main circuit terminal of the power semiconductor module and a positive surface wiring on a surface mounted on the multilayer board, and the positive surface wiring is connected to a 2nth (n represents a positive integer) layer of wiring layers of the multilayer board through a first via hole or a first through-hole; the negative busbar is connected to a negative main circuit terminal of the power semiconductor module and a negative surface wiring on a surface mounted on the multilayer board, and the negative surface wiring is connected to a 2n+1th layer facing the 2nth layer of the multilayer board through a second via hole or a second through-hole; the positive main circuit terminal of the power semiconductor module and the positive busbar are electrically connected by a first fixing member; and the negative main circuit terminal of the power semiconductor module and the negative busbar are electrically connected by a second fixing member.

In addition, according to the present invention, an in-car electrical system using the power converter of each of the foregoing inventions can be provided. Namely, the in-car electrical system configured as follows can also be provided, where a direct current power which is supplied to the positive main circuit terminal and negative main circuit terminal of the power semiconductor module is converted into an alternate current power by using the power converter of each of the inventions, and the alternate current power is supplied to a motor from the alternate main circuit terminal.

### Effects of the Invention

According to the present invention, in a power converter including a power semiconductor module for performing a power control and a multilayer board on which a busbar for feeding a main circuit current and a control device are mounted, a direct current is supplied to the power semiconductor module by connecting a positive busbar and a negative busbar to an even number layer wiring and an odd number layer wiring, respectively, within the multilayer board. This makes currents in neighboring layers of the multilayer board flow in an opposite direction to each other. Therefore, the electromagnetic energy is cancelled and a wiring inductance can be reduced. Accordingly, a power converter which can output large power by applying a large current can be provided with a small size and at low cost, by lowering the inductance of an input/output circuit and using the busbar.

### BRIEF DESCRIPTION OF THE DRAWINGS

FIG. 1 is an exploded perspective view showing a power converter according to a first embodiment of the present invention;

FIG. 2 is a circuit diagram showing a main part of the power converter shown in FIG. 1;

FIG. 3 is a circuit diagram showing an internal circuit of a power semiconductor module shown in FIG. 2;

FIG. 4 is a partial cross sectional view showing a portion of the electrolytic capacitor and the power semiconductor module of the power converter shown in FIG. 1 by cutting linearly;

FIG. 5A and FIG. 5B are partial cross sectional views showing a multilayer board of the power converter shown in FIG. 1, and FIG. 5A shows a cross section of the multilayer board around a busbar connection hole of a positive busbar and FIG. 5B shows a cross section of the multilayer board around a busbar connection hole of a negative busbar;

FIG. 6A to FIG. 6D are exploded plan views showing a positive busbar, a negative busbar and a multilayer board by each layer within a dotted line area A of the power converter shown in FIG. 1, and FIG. 6A shows a busbar area (layer), FIG. 6B shows a surface wiring area (layer) of the multilayer board, FIG. 6C shows a second wiring area (layer) of the multilayer board and FIG. 6D shows a third wiring area (layer) of the multilayer board;

FIG. 7 is an exploded perspective view showing a power converter according to a second embodiment of the present invention;

FIG. 8 is an exploded perspective view showing a power converter according to a third embodiment of the present invention;

FIG. 9 is an exploded perspective view showing a power converter according to a fourth embodiment of the present invention;

FIG. 10 is an exploded perspective view showing a power converter according to a fifth embodiment of the present invention;

FIG. 11A to FIG. 11D are exploded plan views showing a positive busbar, a negative busbar and each layer of a multilayer board of the power converter shown in FIG. 10, and FIG. 11A shows a positive busbar and a negative busbar, FIG. 11B shows a surface wiring (positive surface wiring and negative surface wiring) of a first layer of a multilayer board 100, FIG. 11C shows a second layer wiring of a second layer of the multilayer board and FIG. 11D shows a third layer wiring of a third layer of the multilayer board;

FIG. 12 is an exploded perspective view showing a power converter according to a sixth embodiment of the present invention;

FIG. 13A and FIG. 13B are partial cross sectional views showing a portion around a busbar of a multilayer board of a power converter according to a seventh embodiment of the present invention, and FIG. 13A shows a cross section of the multilayer board around a busbar connection hole of a positive busbar and FIG. 13B shows a cross section of the multilayer board around a busbar connection hole of a negative busbar.

### EMBODIMENT OF THE INVENTION

Hereinafter, an explanation for each embodiment of the present invention will be given in detail in reference to each drawing attached herewith.

A power converter (1001-1006) according to an embodiment of the present invention includes a power semiconductor module 500 and a multilayer board (printed board) 100 mounted on the power semiconductor module 500. A busbar that feeds a main circuit current is connected to a surface wiring layer (first layer) of the multilayer board 100 and a control unit (10a-10f) including a control device is disposed on the multilayer board 100. In addition, the busbar is formed to be thicker than a wiring (pattern) of the multilayer board 100. Furthermore, a positive electrode (positive busbar 11) of the busbar is connected to, for example, an even number layer of the multilayer board 100 and a negative electrode (negative busbar 12) of the busbar is connected to a pattern of an odd number layer of the multilayer board 100, by using a via hole (111, 112) or through-hole formed in the multilayer board 100. Of course, the positive electrode (positive busbar 11) of the busbar may be connected to, for example, an odd number layer of the multilayer board 100 and the negative electrode (negative busbar 12) of the busbar may be connected to a pattern of an even number layer of the multilayer board 100. As a result, a power converter (1001-1006) capable of applying a large current can be achieved with a small size and at low cost, as well as low inductance.

### First Embodiment

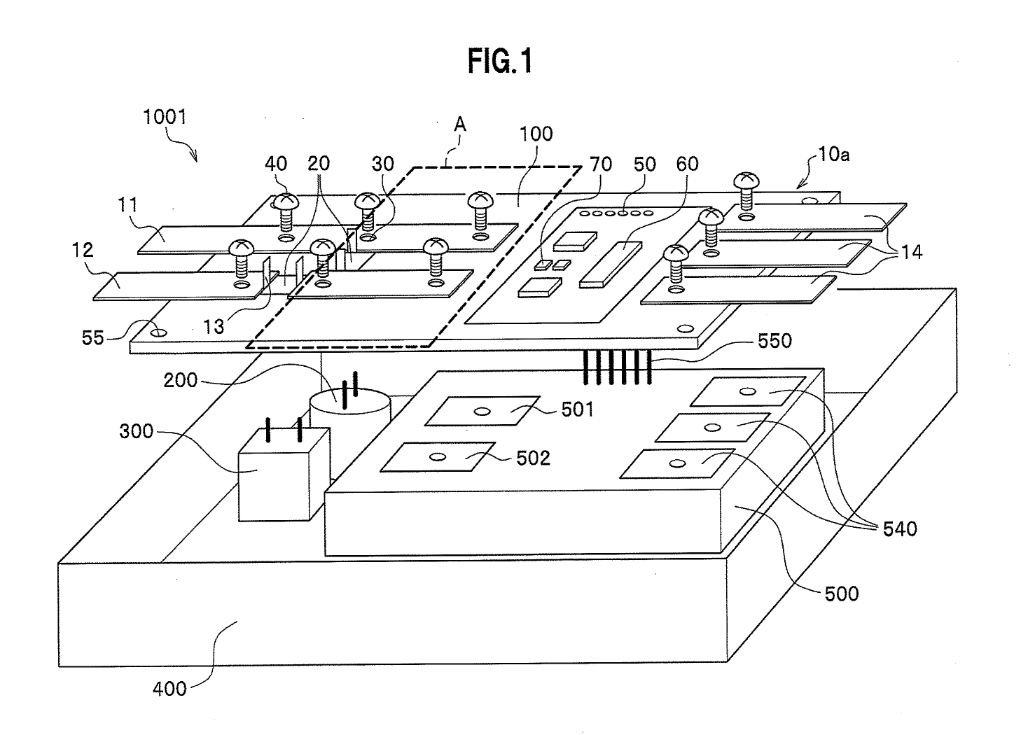

First, an explanation of the power converter 1001 according to the first embodiment of the present invention will be given in reference to FIG. 1 to FIG. 6D.

FIG. 1 is an exploded perspective view showing the power converter 1001 according to the first embodiment of the present invention. Meanwhile, in FIG. 1, the power inverter 1001 is exploded into a power semiconductor module 500 and a control unit 10a consisting of a multilayer board 100. In addition, although the power converter 1001 has a cover for sealing an upper opening of a metal box 400 covering a bottom and side face of the power converter 1001, the cover is omitted in FIG. 1 in order to show the internal structure.

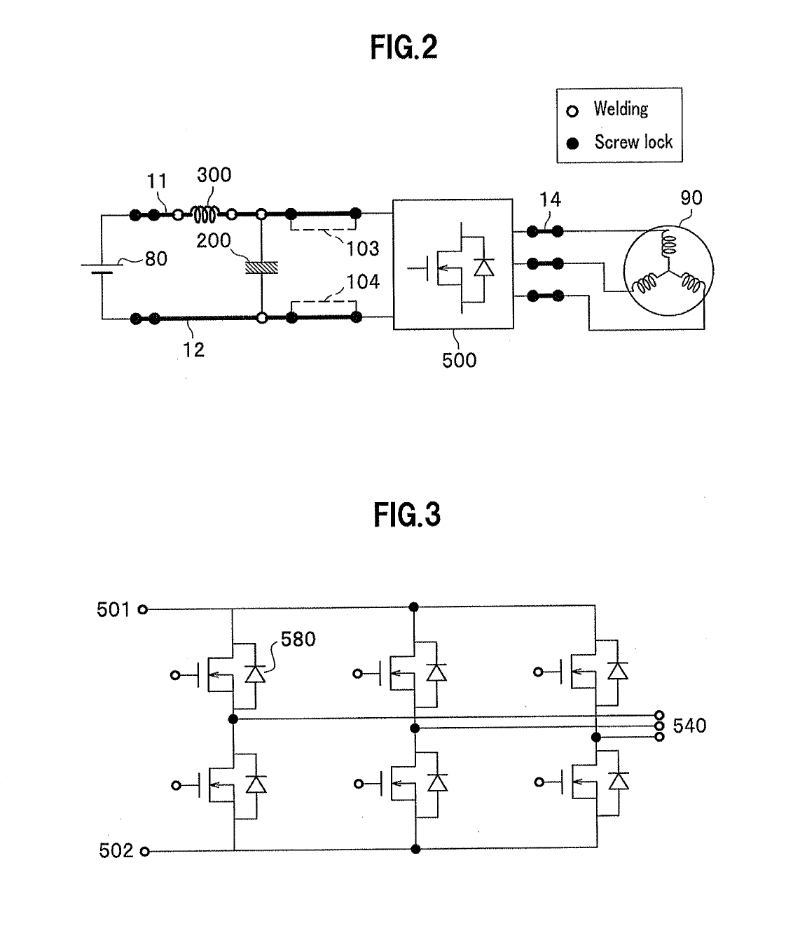

FIG. 2 is a circuit diagram showing a main part of the power converter 1001 shown in FIG. 1. In the circuit diagram shown in FIG. 2, a part indicated by a white circle indicates a connection portion by welding and a part indicated by a black circle indicates a fixed portion by a screw.

Meanwhile, in FIG. 2, the power converter 1001 that supplies an electric power to a motor 90, which is a load, by converting a direct current power of a direct current power source 80, such as a battery, into an alternate current power (other than sign wave electric power, square-wave electric power and trapezoidal electric power formed by switching may also be acceptable, this is the same below), by using the power semiconductor module 500 is shown. However, the embodiment of the present invention is not limited to a direct current-alternate current conversion, and even in a different type of power converter such as a direct current-direct current conversion and an alternate current-direct current conversion, operations and effects similar to those of the power converter shown in FIG. 2 that performs a direct current-alternate current conversion can be obtained, by configuring a structure similar to FIG. 1.

In FIG. 1 and FIG. 2, input/output terminals of the power semiconductor module 500 that converts a direct current power into an alternate current power consists of a positive main circuit terminal 501 handling a positive direct current power, a negative main circuit terminal 502 handling a negative direct current power, an alternate main circuit terminal 540 handling a three-phase alternate current main power, and a control terminal 550 handling a signal and power other than the main power.

FIG. 3 is a circuit diagram showing an internal circuit of the power semiconductor module 500 shown in FIG. 2. As shown in FIG. 3, a circuit configuration of the power semiconductor module 500 consists of a three-phase inverter circuit formed by a bridge configuration of three arms with six MOSFETs 580. It is noted that the circuit configuration of the power semiconductor module 500 is not limited to MOSFET 580, but may a semiconductor device other than MOSFET 580 such as, for example, IGBT (Insulated Gate Bipolar Transistor) or SCR (Silicon Controlled Rectifier) that is a power semiconductor device which is capable of switching control.

In the power converter 1001 according to the embodiment, the power semiconductor module 500 is a so-called “6 in 1” type that packs six devices (MOSFET 580) which perform switching in one package. However, as will be described alter, the power semiconductor module 500 may, be configured using three sets of a so-called “2 in 1” type that packs two devices in one package, or using six discrete devices.

As shown in FIG. 1, a control unit 10a is disposed above the power semiconductor module 500. An integrated circuit 60 including, for example, a control IC for driving a switching device (for example, MOSFET 580 of inverter circuit shown in FIG. 3) within the power semiconductor module 500 as well as an integrated circuit peripheral element 70, and the positive busbar 11, the negative busbar 12 and the alternate busbar 14, which are made of metal having a low electric resistance such as copper, for inputting/outputting electric power of the power semiconductor module 500, are mounted on the multilayer board 100 of the control unit 10a.

In addition, the positive busbar 11, the negative busbar 12, a busbar connection hole 30 for fixing the alternate busbar 14 and the power semiconductor module 500, an element connection hole 20 for connecting the positive busbar 11 and the negative busbar 12 to an electrolytic capacitor 200 and an inductor 300, a though-hole 50 for connecting the control unit 10a of the multilayer board 100 and the control terminal 550 of the power semiconductor module 500, and a board fixing hole 55 for fixing the multilayer board 100 including the control unit 10a to a metal box 400 which has a large heat capacity and a large thermal conductivity such as aluminum, are prepared on the multilayer board 100.

Meanwhile, in the example shown in FIG. 1, the mounting is a single-side mounting where the integrated circuit 60 of the control unit 10a is mounted on a surface wiring layer (first layer) of the multilayer board 100. However, the mounting may be a double-side mounting where an element of the control unit 10a is also mounted on a back side wiring layer of the multilayer board 100. In addition, instead of the electrolytic capacitor 200, other type of capacitors having a sufficient electrostatic capacity may be used.

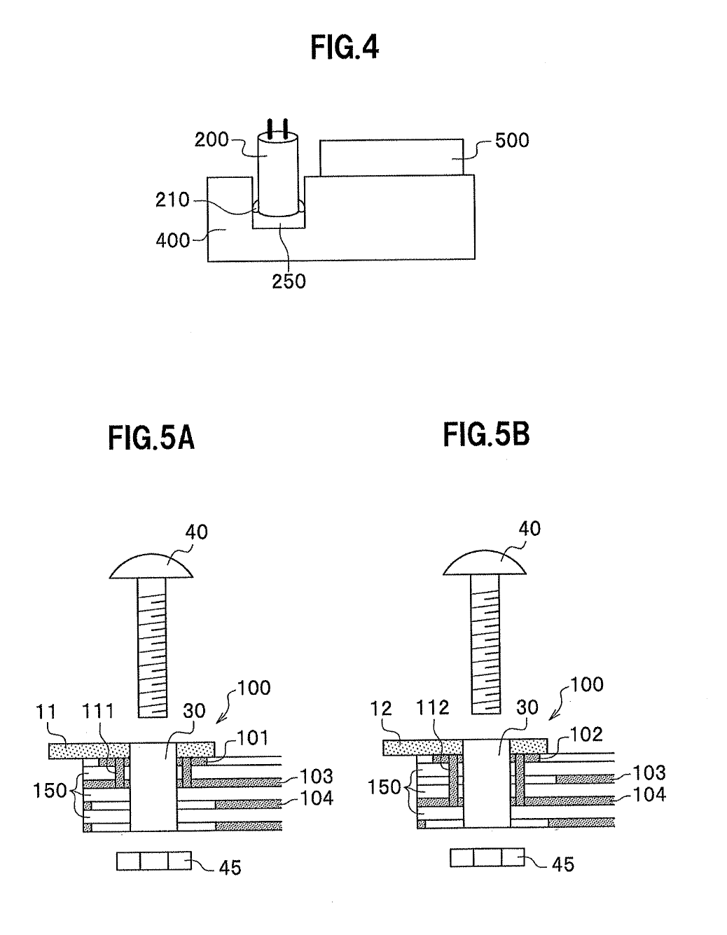

FIG. 4 is a partial cross sectional view showing a portion of the electrolytic capacitor 200 and the power semiconductor module 500 of the power converter 1001 shown in FIG. 1 by cutting linearly.

As shown in FIG. 4, a groove 250 is formed in the metal box 400, which is arranged below the power semiconductor module 500, for positioning the electrolytic capacitor 200. In addition, the electrolytic capacitor 200 is fixed to the bottom of the metal box 400 by a fixing adhesive agent 210.

It is noted that, although specifically not shown, the inductor 300 is also fixed to the bottom of the metal box 400 by a fixing adhesive agent by forming a groove in the metal box 400 as with the case of the electrolytic capacitor 200.

In addition, as shown in FIG. 2, on the direct current power side, a direct current power source 80 consisting of, for example, a rectifying/smoothing circuit and a battery is fixed to ends of the positive busbar 11 and negative busbar 12 on a side opposite to the side where the power semiconductor module 500 is connected. Furthermore, on the alternate current power side, for example, a load such as the motor 90 and a control target are fixed to ends of the alternate busbars 14 on a side opposite to the side where the power semiconductor module 500 is connected.

FIG. 5A and FIG. 5B are partial cross sectional views showing the multilayer board 100 of the power converter 1001 shown in FIG. 1, and FIG. 5A shows a cross section of the multilayer board 100 around a busbar connection hole 30 of the positive busbar 11 and FIG. 5B shows a cross section of the multilayer board 100 around a busbar connection hole 30 of the negative busbar 12.

First, an assembly process of the power converter 1001 shown in FIG. 1 will be explained in reference to FIG. 5A and FIG. 5B.

In the assembly process of the power converter 1001 shown in FIG. 1, first, the power semiconductor module 500 is fixed to the bottom of the metal box 400 by screws through, for example, a heat-transfer grease (for instance, paste a heat-transfer grease on the joint surfaces or sandwich a thermal conductive sheet between the joint surfaces).

Next, as shown in FIG. 5A and FIG. 5B, the positive busbar 11 and the negative busbar 12 are fixed by a screw 40 and a nut 45 to the busbar connection hole 30 of the multilayer board 100 on which the integrated circuit 60 and the like are soldered by reflow-soldering and the like.

In FIG. 1, the power semiconductor module 500, the positive busbar 11 and the negative busbar 12 as well as the alternate busbar 14 and the control unit 10a of the multilayer board 100 are fixed to each other by screwing the screws 40 into screw holes (prepare female screw in advance) of the positive main circuit terminal 501, the negative main circuit terminal 502 and the alternate main circuit terminal 540 of the power semiconductor module 500. In addition, the multilayer board 100 is fixed to the metal box 400 by a screw through the board fixing hole 55. Furthermore, the control terminal 550 of the power semiconductor module 500 and a though-hole 50 of the control unit 10a are electrically connected by spot-soldering and the like. After the connection, the electrolytic capacitor 200 and the inductor 300 which are fixed to the metal box 400 in advance are connected to a busbar terminal 13 of each of the positive busbar 11 and the negative busbar 12 by TIG welding (Tungsten Inert Gas Welding) and the like.

Next, a connection configuration between the positive busbar as well as the negative busbar and a wiring of each layer of the multilayer board 100 will be explained in reference to FIG. 5A and FIG. 5B. Here, the multilayer board 100 having four layers is exemplified, and each of the layers is sequentially called (that is, from the upper to the bottom) as a first layer, a second layer, a third layer and a fourth layer from a surface side to which the positive busbar 11 and the negative busbar 12 are connected. In FIG. 5A and FIG. 5B, a conductive portion of the multilayer board 100 is shown with shading.

As shown in FIG. 5A, the positive busbar 11 is electrically connected to a positive surface wiring 101 of the first layer of the multilayer board 100 by direct contact. In addition, a positive via hole 111 is disposed in the multilayer board 100, and the positive surface wiring 101 is connected to a second layer wiring 103 of the second layer through the positive via hole 111. Namely, the positive busbar 11 and the second layer wiring 103 that is an inner layer wiring of the multilayer board 100 are connected in a sequence of positive busbar 11→positive surface wiring 101→positive via hole 111→second layer wiring 103 of the inner layer wiring.

In addition, as shown in FIG. 5B, the negative busbar 12 is electrically connected to a negative surface wiring 102 of the first layer of the multilayer board 100 by direct contact. In addition, a negative via hole 112 is disposed in the multilayer board 100, and the negative surface wiring 102 is connected to a third layer wiring 104 of the third layer through the negative via hole 112. Namely, the negative busbar 12 and the third layer wiring 104 that is an inner layer wiring of the multilayer board 100 are connected in a sequence of negative busbar 12→negative surface wiring 102→negative via hole 112→third layer wiring 104 of the inner layer wiring.

Meanwhile, instead of the positive via hole 111, a through-hole connecting the positive surface wiring 101 and the second layer wiring 103 may be disposed on an inner wall of the busbar connection hole 30. Similarly, instead of the negative via hole 112, a through-hole connecting the negative surface wiring 102 and the third layer wiring 104 may be disposed on the inner wall of the busbar connection hole 30.

In addition, although specifically not shown, the alternate busbar 14 is mounted under the condition that the alternate busbar 14 is connected to any one of independent layers of the multilayer board 100 on the direct current side, or not connected to any layer wiring of the multilayer board 100.

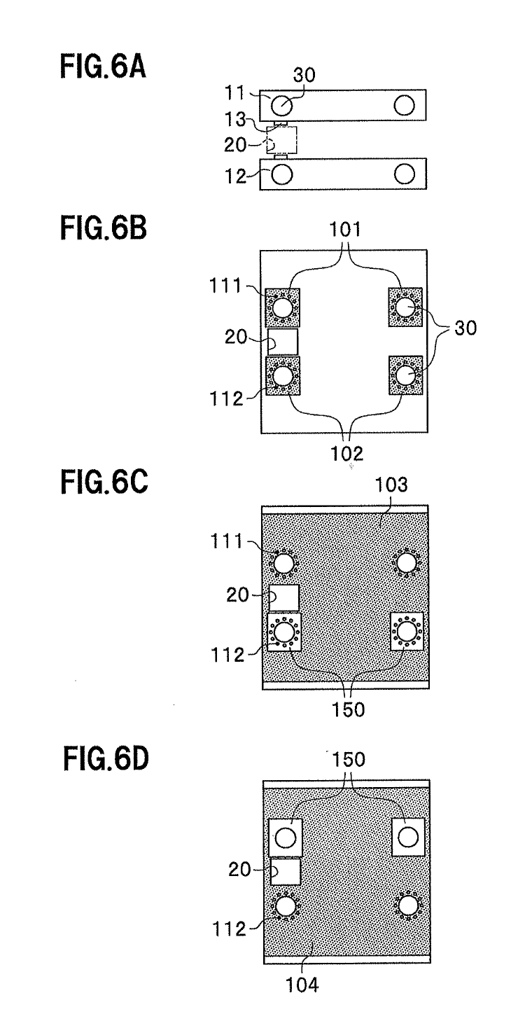

FIG. 6A to FIG. 6D are exploded plan views showing the positive busbar 11, the negative busbar 12 and the multilayer board 100 by each layer within a dotted line area A of the power converter 1001 shown in FIG. 1, and FIG. 6A shows a busbar area (layer), FIG. 6B shows a surface wiring area (layer) of the multilayer board 100, FIG. 6C shows a second wiring area (layer) of the multilayer board 100 and FIG. 6D shows a third wiring area (layer) of the multilayer board 100.

As shown in FIG. 6A, on both sides of an element connection hole 20 for connecting the electrolytic capacitor 200 to a busbar terminal 13, the busbar connection hole 30 for connecting and fixing the positive busbar 11 and the negative busbar 12 to the multilayer board 100 is disposed. In addition, as shown in FIG. 6B, FIG. 6C and FIG. 6D, a plurality of via holes (positive via hole 111 and negative via hole 112) are disposed around the busbar connection hole 30 of each of the positive busbar 11 and the negative busbar 12. The positive via hole 111 which is disposed around the busbar connection hole 30 of the positive busbar 11 is connected to the second layer wiring 103 of the second layer shown in FIG. 6C from the positive surface wiring 101 of the first layer shown in FIG. 6B. In addition, the negative via hole 112 which is disposed around the busbar connection hole 30 of the negative busbar 12 is connected to the third layer wiring 104 of the third layer shown in FIG. 6D from the negative surface wiring 102 of the first layer shown in FIG. 6B.

Namely, in the second layer wiring 103 of FIG. 6C, an area of an insulating material 150 (see FIG. 5A and FIG. 5B) is disposed so as to surround the busbar connection hole 30 for fixing the negative busbar 12 and the negative via hole 112, and a solid pattern is formed in the area other than the insulating material 150. Then, the positive busbar 11 of FIG. 6A, the positive surface wiring 101 of FIG. 6B and the second layer wiring 103 of FIG. 6C are connected to each other. In addition, in the third layer wiring 104 of FIG. 6D, an area of the insulating material 150 is disposed so as to surround the busbar connection hole 30 for fixing the positive busbar 11 and the positive via hole 111, and a solid pattern is formed in the area other than the insulating material 150. Then, the negative busbar 12 of FIG. 6A, the negative surface wiring 102 of FIG. 6B and the third layer wiring 104 of FIG. 6D are connected to each other.

It is noted that the solid pattern means a pattern which is different from a general conductor pattern on a print board that is formed in a narrow band having a predetermined width, and is formed in an area being not occupied by other electrical polarity pattern, while avoiding in contact with the other polarity pattern.

The insulating material 150 disposed in an inner layer of the multilayer board 100 as shown in FIG. 6C and FIG. 6D can obtain a sufficient dielectric breakdown voltage with a thickness of about several hundred microns. For example, when a thickness of the insulating material 150 is about 70 m, the dielectric breakdown voltage of several kV can be obtained. As the thickness of the insulating material 150 becomes thinner and as the dielectric constant of the insulating material 150 becomes higher, a capacitance distributing between wirings each of which having different electrical polarity and facing each other sandwiching the insulating material 150 between the wirings increases. A positive reactance generated by an inductance distributing in the wiring is cancelled by a negative reactance to be generated by a capacitance distributing between the wirings, and an impedance for a high frequency component of a current flowing in these wirings becomes small.

In addition, the second layer wiring 103 of FIG. 6C and the third layer wiring 104 of FIG. 6D are closely arranged facing each other with a wide area by the solid patterns each of which is formed in a wide region. In addition, the second layer wiring 103 and the third layer wiring 104 are arranged adjacently so that main circuit currents of the positive side and the negative side flowing into the power semiconductor module 500 flow in the opposite direction to each other. By forming the multilayer board 100 as described above, direct currents of the second layer wiring 103 and the third layer wiring 104 that are inner layer wirings flow in the opposite direction to each other (that is, the currents flow so as to cancel magnetic field). Therefore, a wiring inductance between the electrolytic capacitor 200 and the power semiconductor module 500 can be reduced to the minimum. As a result, it becomes that a high-frequency current easily flows in the inner layer wiring that has a low inductance. In other words, a current of high-frequency component which flows when the power semiconductor module 500 is operated, that is, a current having a small peak value flows in the inner layer wirings (that is, the second layer wiring 103 and third layer wiring 104) having a low inductance.

In addition, generally, a thickness of a pattern wiring (that is, positive surface wiring 101, negative surface wiring 102, second layer wiring 103, and third layer wiring 104) of each layer of the multilayer board 100 is about dozens to hundreds of On the other hand, a thickness of the positive busbar 11 and the negative busbar 12 may be increased dozens to hundreds times thicker than that of each pattern wiring of the multilayer board 100. Therefore, most of a current of low-frequency component which flows when the power semiconductor module 500 is operated flows in positive busbar 11 and the negative busbar 12 that have a small electric resistance.

By forming a structure of the power converter 1001 as described above, a current of high-frequency component having a small current value mainly flows in the multilayer board 100 which is hard to dissipate heat due to lamination of the insulating material 150. Then, a generation of joule heat due to a wiring loss can be made small. In addition, since most of a current of the low-frequency component which has a large current value flows in the positive busbar 11 and the negative busbar 12 each having a small electric resistance (resistance), a generation of joule heat due to a wiring loss thereof is easily suppressed and the heat is easily dissipated. As described above, since the positive busbar 11, the negative busbar 12 and the pattern wiring of each layer of the multilayer board 100 are used in combination as a main circuit current path, a temperature rise of the control unit 10a can be suppressed even if a large current is applied. As a result, downsizing of the power converter 1001 and cost reduction due to reduction of elements can be achieved.

In addition, since an inductance between the electrolytic capacitor 200 and the switching device (MOSFET 580) within the power semiconductor module 500 becomes substantially small, a surge voltage of the switching device when each of the MOSFETs 580 of the power semiconductor module 500 is turned off is suppressed. Then, a heat generation due to a switching loss of an inverter circuit can be reduced, and thereby the power converter 1001 can be reduced in size and cost. Furthermore, by reducing the wiring inductance, a snubber circuit which is prepared for suppressing a spike voltage may be eliminated, thereby contributing reduction in size and cost of the power converter 1001 due to reduction of elements of the snubber circuit.

In addition, by reducing a wiring inductance of the main circuit current path, a ripple current to be absorbed by the electrolytic capacitor 200 can be reduced. Then, a heat generation of the electrolytic capacitor 200 can be suppressed, and a capacitance (size) of the electrolytic capacitor 200 can be reduced. In this regard, reduction in size and cost of the power converter 1001 can also be achieved. As described above, the suppression of heat generation and easiness of the mounting of the power converter 1001 according to the embodiment can be achieved, and as a result, a high-output power converter 1001 that is capable of applying a large current can be provided with a small size and at a low cost.

Meanwhile, in the present embodiment, the case that the integrated circuit 60 and the integrated circuit peripheral element 70 are mounted on the multilayer board 100 has been explained. However, in the case when the integrated circuit 60 is not mounted on the multilayer board 100, if a number of wiring layer of the multilayer board 100 is not less than two, operations and effects similar to those of the present embodiment may be obtained. In addition, by forming a solid pattern on each layer below the second layer, while avoiding connection between the positive surface wiring 101 and negative surface wiring 102 of the first layer, a low inductance mounting of a circuit, where a main current flows, can be achieved. In this case, an area other than areas where the positive busbar 11 and the negative busbar 12 come in contact with the positive surface wiring 101 and the negative surface wiring 102, respectively, is insulated in advance by, for example, a resist material.

As described above, in the power converter 1001 according to the first embodiment, the positive busbar 11 and negative busbar 12 for feeding a main circuit current are disposed in the control unit 10a which includes the multilayer board 100 and the control device, and a thickness of the positive busbar 11 and negative busbar 12 is formed to be thicker than that of at least the metal wiring pattern of each layer of the multilayer board 100. In addition, the positive busbar 11 is connected to the 2nth layer wiring (even number layer wiring) of the multilayer board 100, and the negative busbar 12 is connected to the 2n+1th layer wiring (odd number layer wiring) facing the 2nth layer wiring of the multilayer board 100. Therefore, current directions of the 2nth layer wiring (even number layer wiring) and the 2n+1th layer wiring (odd number layer wiring) become opposite to each other, and accordingly, it becomes possible to achieve reduction in size and cost as well as a low inductance of the power converter 1001, which is high-output by a large current application. It is noted that even if the positive busbar 11 is connected to the 2n+1th layer wiring (odd number layer wiring) of the multilayer board 100 and the negative busbar 12 is connected to the 2nth layer wiring (even number layer wiring) facing the 2n+1th layer wiring of the multilayer board 100, currents flowing in the neighboring layers are opposite to each other, and accordingly, reduction in size and cost as well as a low inductance of the power converter 1001 can be achieved as with the foregoing case.

### Second Embodiment

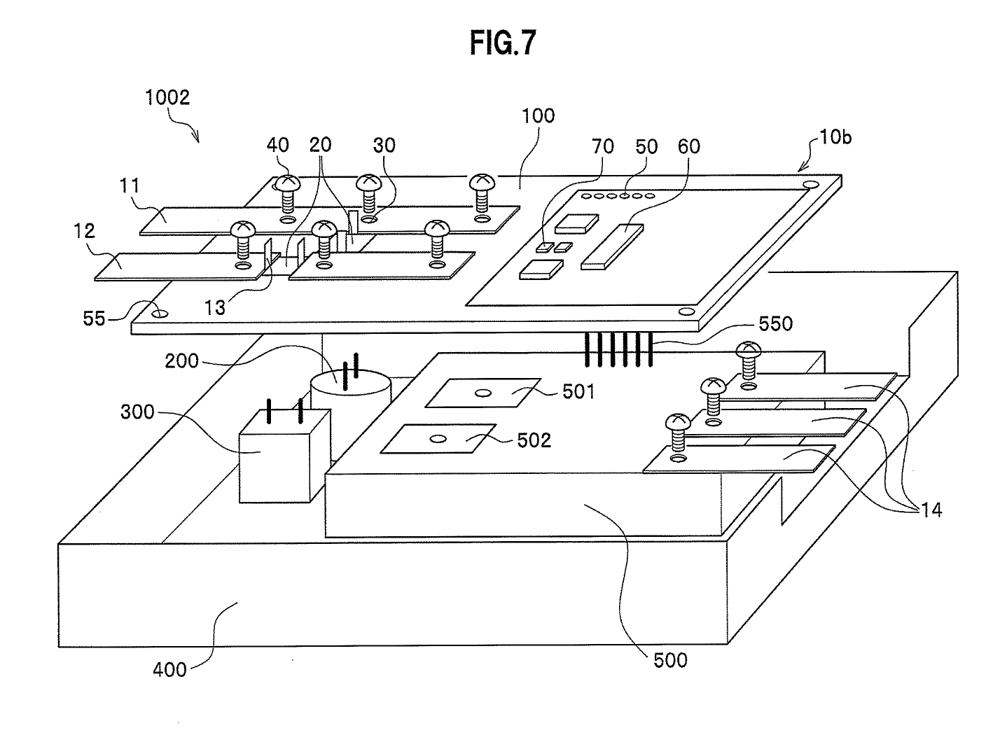

FIG. 7 is an exploded perspective view showing a power converter 1002 according to a second embodiment of the present invention.

Meanwhile, in the following explanation, an element substantially identical to the foregoing element is given the same reference number, and a duplicated explanation will be omitted.

Because of the foregoing reason (enable a high-frequency current to flow easily), it is required that an inductance of a main circuit current path including the positive busbar 11 and the negative busbar 12 on the direct current side is made to be small. However, there is a case that an inductance of a main circuit current path including the alternate busbar 14 on the alternate current side is not necessarily required to be small in comparison with the inductance of the main circuit current path on the direct current side. Namely, when an inverter frequency of the power converter 1002 is not so high (for example, in the case that the inverter frequency is in a range of about commercial frequency), a high-frequency component from the alternate output of the power semiconductor module 500 is small enough and substantially negligible. Therefore, it is unnecessary to have an output current of the power semiconductor module 500 flow in the inner layer wiring having a low inductance.

Then, as shown in FIG. 7, the alternate busbar 14 is directly connected to the alternate main circuit terminal 540 (not shown in FIG. 7 because the terminal 540 is hidden below the busbar 14) of the power semiconductor module 500 without going through each layer wiring of the multilayer board 100 of a control unit 10b. Therefore, since the alternate busbar 14 is not mounted on the multilayer board 100 of the control unit 10b, a large effective area for mounting each element of the control unit 10b can be secured on the multilayer board 100. As a result, more devices such as the integrated circuit 60 may be mounted on the multilayer board 100.

### Third Embodiment

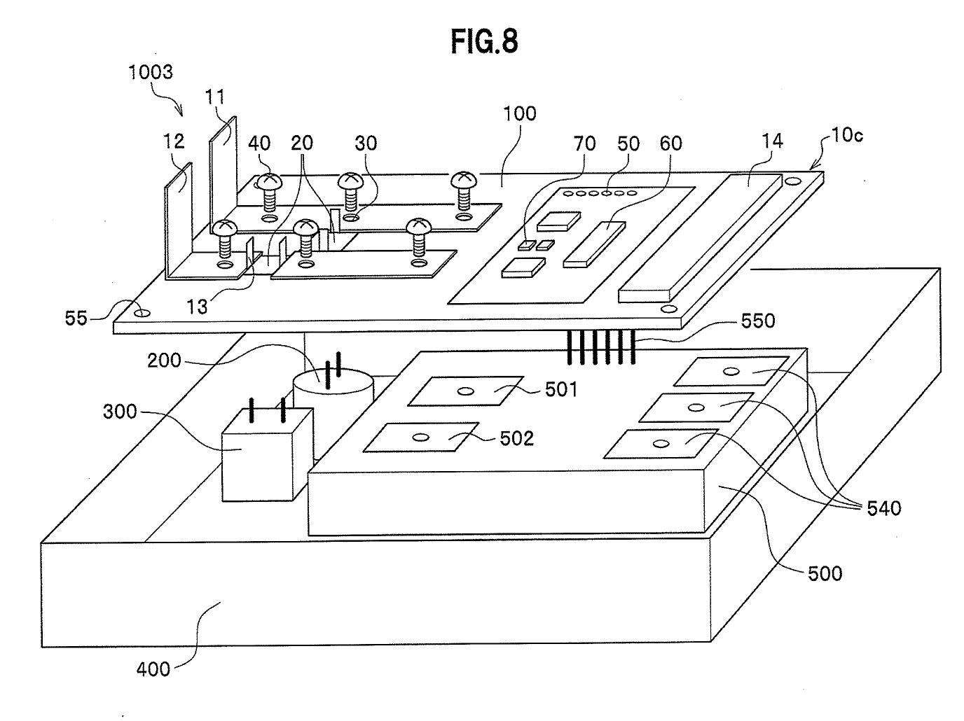

FIG. 8 is an exploded perspective view showing a power converter 1003 according to a third embodiment of the present invention.

As shown in FIG. 8, each end portion of the positive busbar 11 and the negative busbar 12 rises up vertically from a surface of the multilayer board 100 of a control unit 10c. Since the positive busbar 11 and the negative busbar are made of a material having good workability such as copper and aluminum, a degree of freedom of the layout and shape is high. Therefore, a position and shape of an input/output terminal (for example, positive busbar 11 and negative busbar 12) of the power converter 1003 may be designed freely in accordance with an external equipment. Namely, as shown in FIG. 8, the positive busbar 11 and the negative busbar 12 can be risen up vertically from the surface of the multilayer board 100 in accordance with a terminal fixing condition of the external equipment. As a result, it becomes possible to effectively utilize a space of the external equipment where the power converter 1003 is mounted. In addition, by using a connector (in other words, terminal block) for the output of the alternate current side, mountability and maintainability of the power converter 1003 are further improved.

### Fourth Embodiment

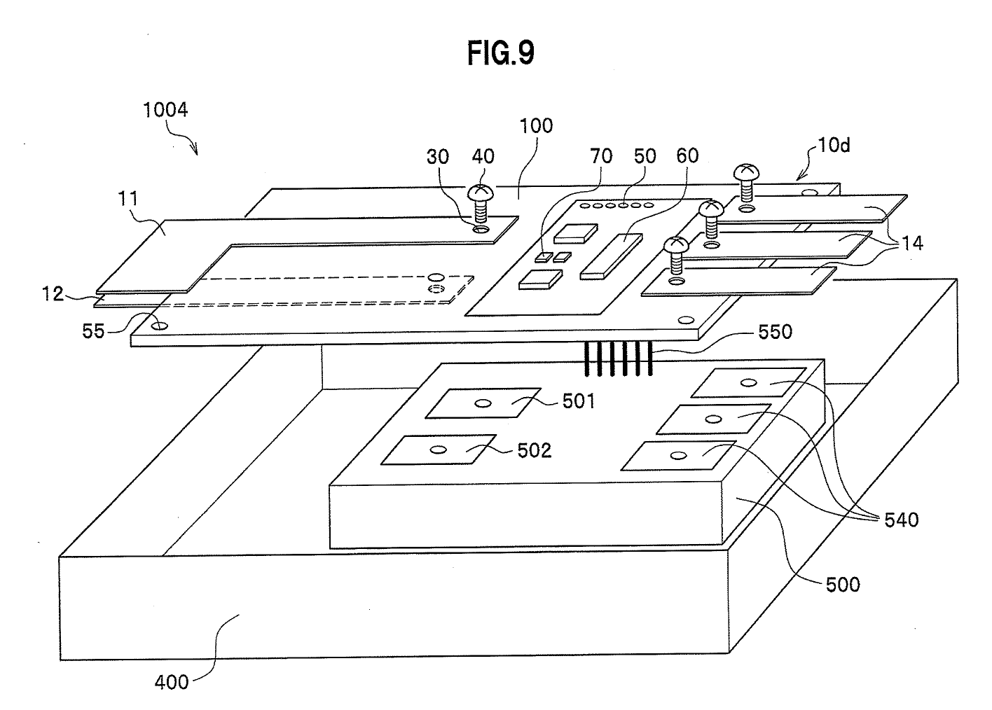

FIG. 9 is an exploded perspective view showing a power converter 1004 according to a fourth embodiment of the present invention.

As shown in FIG. 9, the negative busbar 12 is mounted on a surface of the multilayer board 100 opposite to the surface on which the positive busbar 11 is mounted. Namely, the positive busbar 11 and the negative busbar 12 are mounted on the multilayer board 100 facing each other, while sandwiching the multilayer board 100 between them. Therefore, an electrode of the positive busbar 11 faces the electrode of the negative busbar 12 at a distance of a thickness of the multilayer board 100. In this case, as shown in FIG. 9, the electrolytic capacitor 200 and the inductor 300 shown in FIG. 1 are not in an area of the multilayer board 100, and it is preferable that the electrolytic capacitor 200 and the inductor 300 are mounted on the area outside the area of the multilayer board 100.

According to the fourth embodiment of the present invention, since a wiring inductance on the direct current side can be further reduced, operations and effects similar to those of the first embodiment can be obtained. In addition, since an area that the positive busbar 11 faces the negative busbar 12 is set only in the area outside the multilayer board 100, it becomes possible to reduce the cost and weight of the power converter 1004. In addition, when a direct current power source is introduced by two busbars (not shown) facing each other, while sandwiching a dielectric material between them, the connection is easily implemented and a power loss at the connection becomes smaller.

### Fifth Embodiment

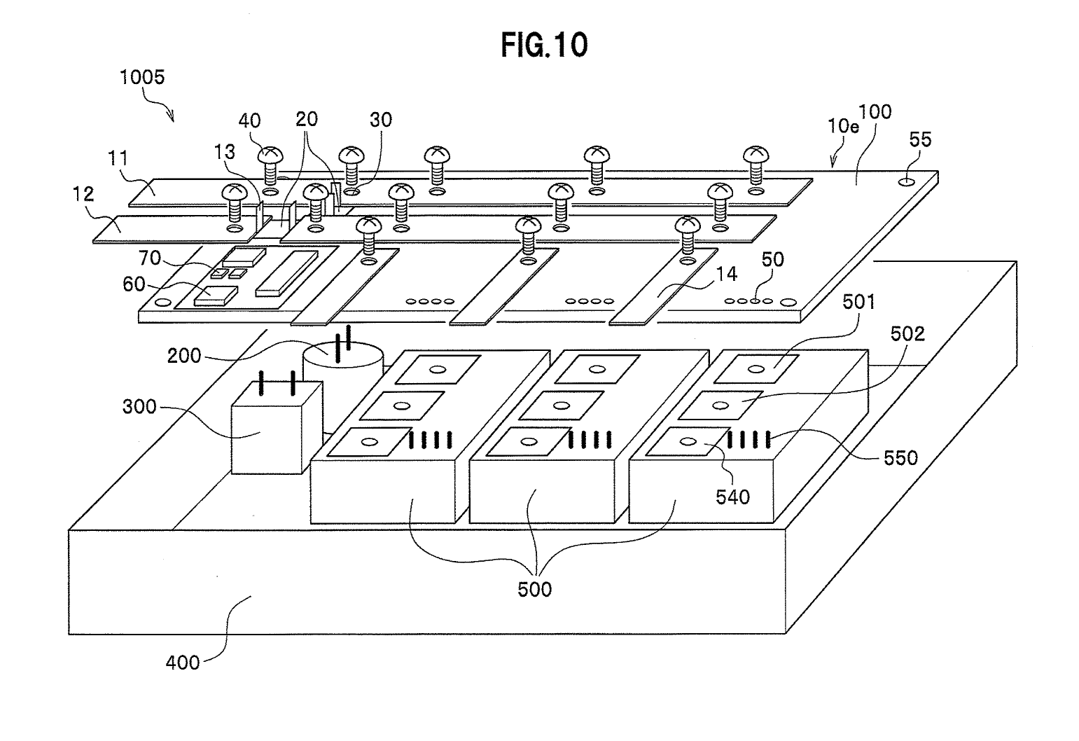

FIG. 10 is an exploded perspective view showing a power converter 1005 according to a fifth embodiment of the present invention.

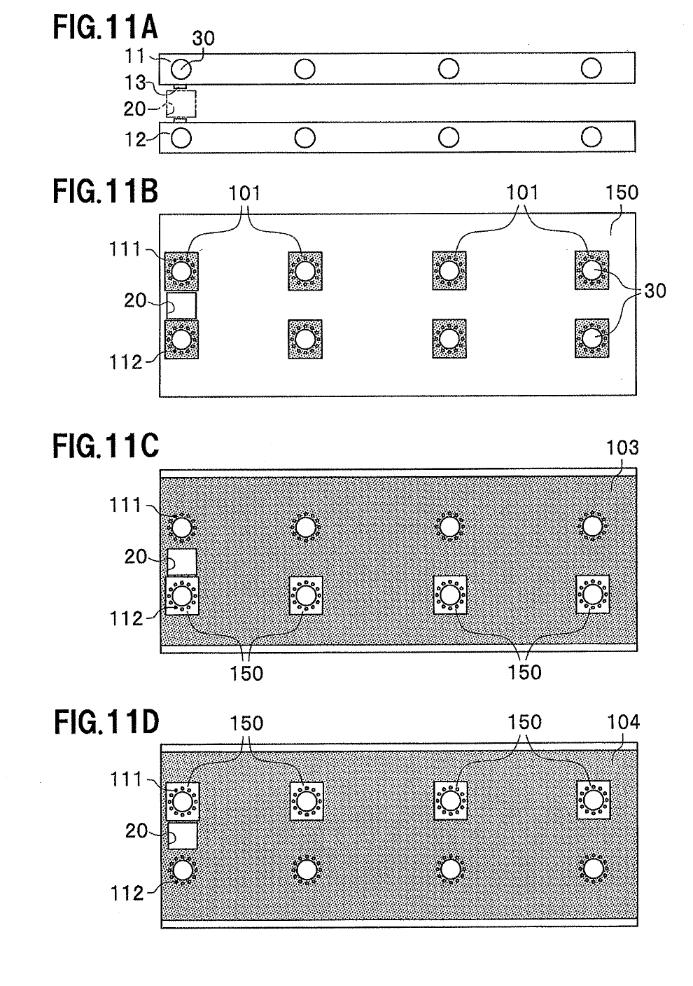

In addition, FIG. 11A to FIG. 11D are exploded plan views showing the positive busbar 11, the negative busbar 12 and each layer of the multilayer board 100 of the power converter 1005 shown in FIG. 10, and FIG. 11A shows the positive busbar 11 and the negative busbar 12, FIG. 11B shows a surface wiring (positive surface wiring 101 and negative surface wiring 102) of the first layer of the multilayer board 100, FIG. 11C shows the second layer wiring 103 of the second layer of the multilayer board 100 and FIG. 11D shows the third layer wiring 104 of the third layer of the multilayer board 100.

In comparison with the power converter 1001 according to the first embodiment shown in FIG. 1, which has the power semiconductor module 500 that is a so-called “6 in 1” type, the power converter 1005 according to the fifth embodiment shown in FIG. 10 is different in that the power semiconductor module 500 consists of three sets of “2 in 1” type module that packs two devices in one package. Accordingly, structures of the positive busbar 11, the negative busbar 12 and the multilayer board 100 shown in FIG. 11A to FIG. 11D are different from those shown in FIG. 6A to FIG. 6D.

Specifically, as shown in FIG. 10 and FIG. 11A, the positive busbar 11 and the negative busbar 12 are connected by screws 40 through the busbar connection holes 30 disposed in each positive main circuit terminal 501 and each negative main circuit terminal 502 of the three power semiconductor modules 500 and the multilayer board 100.

In addition, as with the surface wiring shown in FIG. 11B, in the first layer of the multilayer board 100 of a control unit 10e, the positive surface wiring 101 and negative surface wiring 102 around the busbar connection holes 30 are exposed.

Therefore, the positive busbar 11 and the positive surface wiring 101 are electrically connected by direct contact. In addition, the negative busbar 12 and the negative surface wiring 102 are electrically connected by direct contact. Furthermore, many positive via holes ill and many negative via holes 112 are disposed around the busbar connection holes 30. Therefore, the positive surface wiring 101 shown in FIG. 11B is electrically connected to the second layer wiring 103 shown in FIG. 11C through the positive via hole 111, and the negative surface wiring 102 shown in FIG. 11B is electrically connected to the third layer wiring 104 shown in FIG. 11D through the negative via hole 112.

As described above, in the power converter 1005, the positive busbar 11 and the negative busbar 12 on the direct current side, the second layer wiring 103 and the third layer wiring 104 of the multilayer board 100, and each positive main circuit terminal 501 and each negative main circuit terminal 502 of the three power semiconductor modules 500 on the direct current side are connected. With the foregoing configuration, according to the fifth embodiment, a wiring conductance between the electrolytic capacitor 200 and the positive main circuit terminal 501 as well as the negative main circuit terminal 502 on the direct current side of the power semiconductor module 500 consisting of three “2 in 1” modules can be reduced. As a result, a loss of the power converter 1005 can be reduced.

### Sixth Embodiment

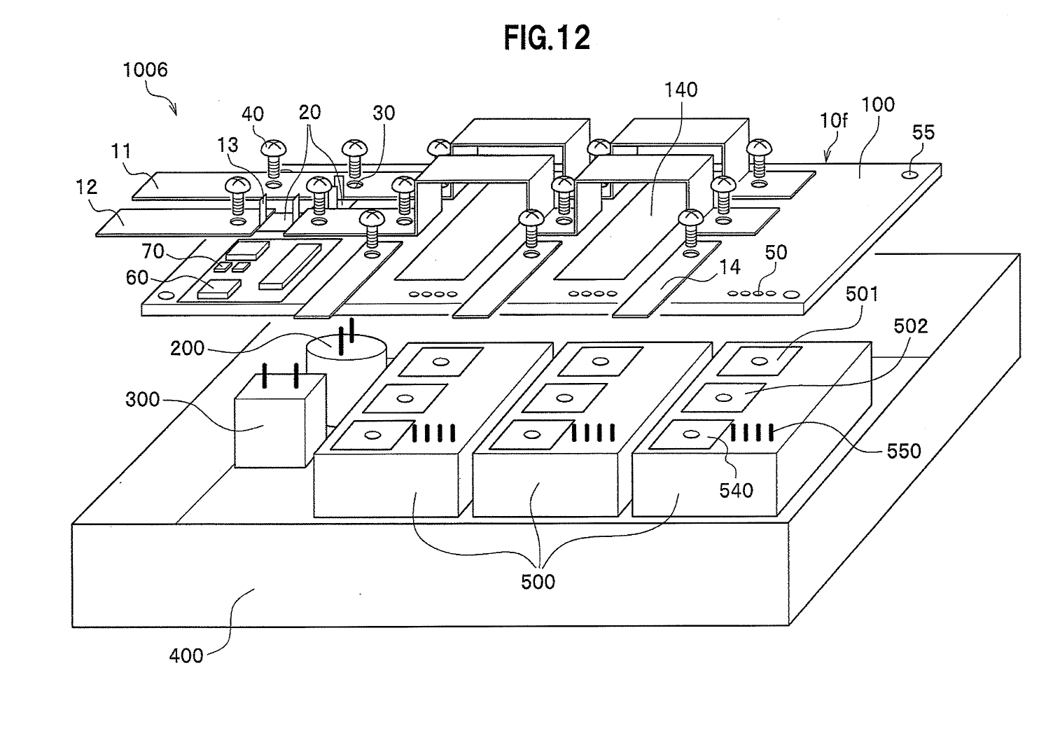

FIG. 12 is an exploded perspective view showing a power converter 1006 according to a sixth embodiment of the present invention.

The power converter 1006 according to the sixth embodiment is different from the power converter 1005 according to the fifth embodiment in that the positive busbar 11 and the negative busbar 12 are formed in three dimensions over circuit elements (area that circuit elements are mounted) in a control unit 10f.

According to the sixth embodiment of the present invention, for example, the integrated circuit 60 may be mounted on an integrated circuit mounting area 140 of the multilayer board 100 before mounting the positive busbar 11 and the negative busbar 12. In addition, the area of the multilayer board 100 can be effectively utilized, thereby resulting in reduction in size of the power converter 1006.

### Seventh Embodiment

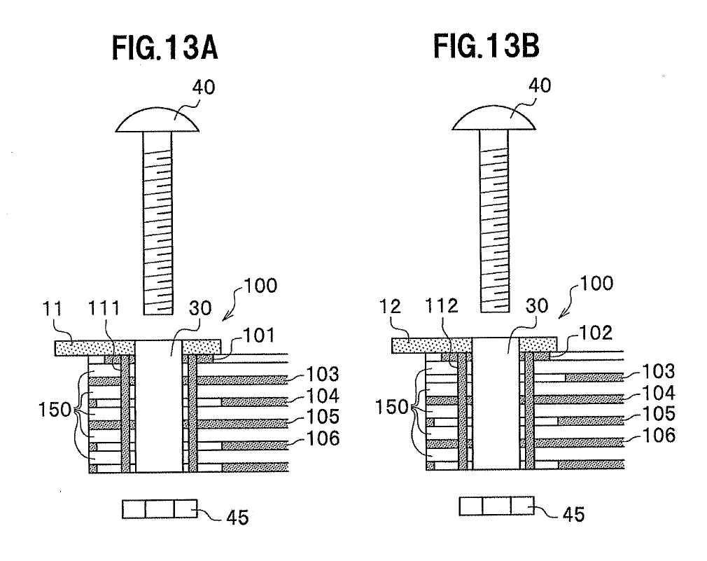

FIG. 13A and FIG. 13B are partial cross sectional views showing a portion around a busbar of the multilayer board 100 of a power converter according to a seventh embodiment of the present invention, and FIG. 13A shows a cross section of the multilayer board 100 around the busbar connection hole 30 of the positive busbar 11 and FIG. 13B shows a cross section of the multilayer board 100 around the busbar connection hole 30 of the negative busbar 12.

In comparison with the multilayer board 100 according to the first embodiment shown in FIG. 5A and FIG. 5B, the multilayer board 100 according to the seventh embodiment shown in FIG. 13A and FIG. 13B is different in that the multilayer board 100 according to the seventh embodiment consists of a six-layer board.

As shown in FIG. 13A, the positive busbar 11 is in contact with the positive surface wiring 101 of the first layer, and electrically connected to the second layer wiring 103 and a fourth layer wiring 105 through the positive via hole 111. In addition, as shown in FIG. 13B, the negative busbar 12 is in contact with the negative surface wiring 102 of the first layer, and electrically connected to the third layer wiring 104 and a fifth layer wiring 106 through the negative via hole 112.

Each of these inner layer wirings (second layer wiring 103 to fifth layer wiring 106) consists of a solid pattern formed in such a manner that a wiring of one electrical polarity avoids the wiring of the other electrical polarity by the busbar connection holes 30 for fixing the positive busbar 11 as well as the negative busbar 12 and an insulating material (for example, insulating material 150 shown in FIG. 11B). For example, as shown in FIG. 6C, a solid pattern of the second layer wiring 103 connected to the positive busbar 11 and positive surface wiring 101 is formed so as to avoid a wiring (negative surface wiring 102) having an electrical polarity opposite to the positive electrical polarity by the insulating material 150. In addition, as shown in FIG. 6D, a solid pattern of the third layer wiring 104 connected to the negative busbar 12 and negative surface wiring 102 is formed so as to avoid a wiring (positive surface wiring 101) having an electrical polarity opposite to the negative electrical polarity by the insulating material 150.

According to the seventh embodiment of the present invention, further lowering of the inductance of the wiring and high-output of the power converter can be achieved, thereby further reduction in size and cost of the power converter can be achieved by reducing the loss and improving the heat dissipation. In addition, in the present embodiment, the inductance and electrical resistance of the wiring are further reduced by using two or more than two inner layer wirings for each of the positive electrical polarity and the negative electrical polarity, and as a result, a further larger current than those of the foregoing embodiments can be applied. Accordingly, it becomes possible to apply the power converter according to the embodiment to the one that has a wider output range. Furthermore, by using the six-layer wiring for the multilayer board 100, a degree of freedom of wiring layout of, for example, the integrated circuit 60 (see FIG. 1) for controlling increases, and thereby a mounting of elements becomes easy, as well as the reduction in size and cost becomes possible.

### SUMMARY

As described above, according to the power converter (1001 to 1006) of each embodiment of the present invention, when wiring layers of two or more than two layers, neighboring and facing each other, of the multilayer board 100 are used as a path of the main circuit current, since the neighboring two layers are bonded utilizing effects of laminating, a low inductance mounting can be achieved by the wiring layers of the multilayer board 100. In addition, since the positive busbar 11 and negative busbar 12 for feeding the main circuit current are formed on one side or on double sides of the multilayer board 100 facing each other, the positive busbar 11 as well as the negative busbar 12 and elements such as the electrolytic capacitor 200 and the inductor 300 can be fixed to each other by, for example, spot welding or screws. Therefore, the mounting of the elements becomes very easy.

In addition, since the screws 40 for fixing the electrodes (positive main circuit terminal 501 and negative main circuit terminal 502) to the power semiconductor module 500 can be commonly utilized for fixing the positive busbar 11 and negative busbar 12 to the multilayer board 100, an assembly workload of the power converter can be reduced. In addition, a free space on the multilayer board 100 that is not occupied by the positive busbar 11 and the negative busbar 12 can be utilized as a control portion by mounting a control device such as a driver IC. Then, a mounting efficiency in the power converter can be improved, and as a result, a further reduction in size of the power converter can be achieved.

In addition, since a connection with a control target such as the motor 90 can be easily implemented by utilizing a connector disposed on the multilayer board 100, usability for the maintenance is much improved. In addition, since positioning of elements such as the electrolytic capacitor 200 and the inductor 300 can be easily implemented by disposing a positioning hole in the metal box 400, and since heat generated by, for example, the electrolytic capacitor 200 and the inductor 300 can be dissipated through the metal box 400, a high heat dissipation mounting of the power converter can be achieved. In addition, by forming the positive busbar 11 and negative busbar 12 in a three dimensional structure, a free space of the multilayer board 100 can be further effectively utilized, and thereby, a further reduction in size and cost of the power converter can also be achieved.

1.-11. (canceled)

12. A power converter, comprising:
a power semiconductor module on which a power semiconductor device is mounted;
a control device for controlling the power semiconductor module;
a multilayer board for mounting the control device; and
a positive busbar and a negative busbar for inputting/outputting electric power to and from the power semiconductor module,
wherein the positive busbar and the negative busbar are mounted on one side of the multilayer board;
wherein the positive busbar is connected to a positive main circuit terminal of the power semiconductor module and a positive surface wiring on a surface mounted on the multilayer board, and the positive surface wiring is connected to a 2nth, n representing positive integer, layer of wiring layers of the multilayer board through a first via hole or a first through-hole;
wherein the negative busbar is connected to a negative main circuit terminal of the power semiconductor module and a negative surface wiring on a surface mounted on the multilayer board, and the negative surface wiring is connected to a 2n+1th layer facing the 2nth layer of the multilayer board through a second via hole or a second through-hole;
wherein the positive main circuit terminal of the power semiconductor module and the positive busbar are electrically connected by a first fixing member; and
wherein the negative main circuit terminal of the power semiconductor module and the negative busbar are electrically connected by a second fixing member.

13. A power converter, comprising:
a power semiconductor module on which a power semiconductor device is mounted;
a control device for controlling the power semiconductor module;
a multilayer board for mounting the control device; and
a positive busbar and a negative busbar for inputting/outputting electric power to and from the power semiconductor module,
wherein the positive busbar is mounted on one side of the multilayer board and the negative busbar is mounted on the other side of the multilayer board, the positive busbar and the negative busbar facing each other;
wherein the positive busbar is connected to a positive main circuit terminal of the power semiconductor module and a positive surface wiring on a surface mounted on the multilayer board, and the positive surface wiring is connected to a 2nth, n representing positive integer, layer of wiring layers of the multilayer board through a first via hole or a first through-hole;
wherein the negative busbar is connected to a negative main circuit terminal of the power semiconductor module and a negative surface wiring on a surface mounted on the multilayer board, and the negative surface wiring is connected to a 2n+1th layer facing the 2nth layer of the multilayer board through a second via hole or a second through-hole;
wherein the positive main circuit terminal of the power semiconductor module and the positive busbar are electrically connected by a first fixing member; and
wherein the negative main circuit terminal of the power semiconductor module and the negative busbar are electrically connected by a second fixing member.

14. The power converter according to claim 12, further comprising a capacitor and an inductor,
wherein the capacitor is connected between the positive busbar and the negative busbar in parallel, and the inductor is connected to the positive busbar or the negative busbar in series.

15. The power converter according to claim 13, further comprising a capacitor and an inductor,
wherein the capacitor is connected between the positive busbar and the negative busbar in parallel, and the inductor is connected to the positive busbar or the negative busbar in series.

16. The power converter according to claim 12,
wherein both the 2nth layer wiring and the 2n+1th layer wiring of the multilayer board, or both a surface wiring formed on a surface of the multilayer board and an inner layer wiring formed on an inner layer of the multilayer board are formed by a solid pattern that is a wiring formed in a wide area.

17. The power converter according to claim 13,
wherein both the 2nth layer wiring and the 2n+1th layer wiring of the multilayer board, or both a surface wiring formed on a surface of the multilayer board and an inner layer wiring formed on an inner layer of the multilayer board are formed by a solid pattern that is a wiring formed in a wide area.

18. The power converter according to claim 12,
wherein thicknesses of the positive busbar and the negative busbar are formed to be thicker than a thickness of a wiring formed on each layer of the multilayer board.

19. The power converter according to claim 13,
wherein thicknesses of the positive busbar and the negative busbar are formed to be thicker than a thickness of a wiring formed on each layer of the multilayer board.

20. A power converter, comprising:
a power semiconductor module on which a power semiconductor device is mounted;
a control device for controlling the power semiconductor module;
a multilayer board for mounting the control device; and
a positive busbar and a negative busbar for inputting/outputting electric power to and from the power semiconductor module,
wherein the positive busbar and the negative busbar are mounted on one side of the multilayer board, or the positive busbar is mounted on one side of the multilayer board and the negative busbar is mounted on the other side of the multilayer board, the positive busbar and the negative busbar facing each other;
wherein the positive busbar is connected to a positive main circuit terminal of the power semiconductor module and a positive surface wiring on a surface mounted on the multilayer board, and the positive surface wiring is connected to an even number layer or an odd number layer of wiring layers of the multilayer board through a first via hole or a first through-hole;
wherein the negative busbar is connected to a negative main circuit terminal of the power semiconductor module and a negative surface wiring on a surface mounted on the multilayer board, and the negative surface wiring is connected to the even number layer or the odd number layer which is not connected to the positive surface wiring through a second via hole or a second through-hole;
wherein the positive main circuit terminal of the power semiconductor module and the positive busbar are electrically connected by a first fixing member; and
wherein the negative main circuit terminal of the power semiconductor module and the negative busbar are electrically connected by a second fixing member.

21. The power converter according to claim 20, further comprising a capacitor and an inductor,
wherein the capacitor is connected between the positive busbar and the negative busbar in parallel, and the inductor is connected to the positive busbar or the negative busbar in series.

22. The power converter according to claim 20,
wherein both the positive surface wiring as well as the negative surface wiring formed on a surface of the multilayer board and an inner layer wiring formed on an inner layer of the multilayer board, or only the inner layer wiring is formed by a solid pattern that is a wiring formed in a wide area.

23. The power converter according to claim 20,
wherein thicknesses of the positive busbar and the negative busbar are formed to be thicker than a thickness of a wiring formed on each layer of the multilayer board.

24. The power converter according to claim 12,
wherein the power converter is housed in a metal box.

25. An in-car electrical system using the power converter according to claim 12,
wherein a direct current power supplied to the positive main circuit terminal and the negative main circuit terminal of the power semiconductor module is converted into an alternate current power, and the alternate current power is supplied to a motor from an alternate main circuit terminal.
